(19) United States
(12) Patent Application Publication
(10) Pub. No.: US 2015/0334862 A1
(43) Pub. Date: Nov. 19, 2015

(54) PROTECTIVE SHEET AND ELECTRONIC DEVICE WITH PROTECTIVE SHEET

(71) Applicant: Kabushiki Kaisha Toshiba, Tokyo (JP)

(72) Inventors: Hiroyuki Minaguchi, Higashimatsuyama Saitama (JP); Takayuki Arisaka, Fussa Tokyo (JP); Kyohei Matsumoto, Ome Tokyo (JP)

(21) Appl. No.: 14/637,033

(22) Filed: Mar. 3, 2015

Related U.S. Application Data
(60) Provisional application No. 61/992,574, filed on May 13, 2014.

(51) Int. Cl. H05K 5/03

(52) U.S. Cl. CPC H05K 5/03

(57) ABSTRACT

According to one embodiment, a protective sheet to be attached to an outer surface of a housing of an electronic device is provided. The protective sheet comprises a sheet body formed of a material more flexible than that of the housing and having an external form defined by sides extending along edges of the electronic device, an adhesive layer applied to one entire surface of the sheet body, a notch comprising a closing end positioned in the sheet body and an opening end positioned at the side and extending along an extending direction connecting the closing end and the opening end, and a tab formed on the sheet body at least one side of the extending direction of the notch portion and easily peelable off from the outer surface.

### CROSS-REFERENCE TO RELATED APPLICATIONS

This application claims the benefit of U.S. Provisional Application No. 61/992,574, filed May 13, 2014, the entire contents of which are incorporated herein by reference.

### FIELD

Embodiments described herein relate generally to a protective sheet and an electronic device with a protective sheet.

### BACKGROUND

Generally, in order to efficiently peel off a protective sheet of an electronic device, a notch portion may be formed at a corner of a polygonal insulating resin member enclosing an inner element, and peeling off a protective sheet attached to the insulating resin member from a portion on the notch portion is thereby facilitated.

Such a protective sheet and an electronic device with a protective sheet are required to have no protuberance protruding from the protective sheet to the outside of an attachment surface of the electronic device.

According to one of the embodiments, a protective sheet is attached to an outer surface of a housing of an electronic device comprising at least one flat outer surface having a perimeter defined by a plurality of edges so as to protect the housing. The protective sheet comprises a sheet body comprising a material more flexible than that of the housing and comprising an external form defined by sides extending along the edges of the electronic device, an adhesive layer on one entire surface of the sheet body, a notch portion comprising a closing end in the sheet body and an opening end at one of the sides, the notch portion extending in a direction from the closing end toward the opening end, and a tab portion formed on at least one side of the sheet body with respect to the direction of the notch portion and easily peelable off from the outer surface.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a general view showing an electronic device of an embodiment.

FIG. 2 is a diagram of the electronic device shown from the opposite side of FIG. 1.

FIG. 3 is a general view showing the electronic device of FIG. 1 in a closed state.

FIG. 4 is an explanatory enlarged diagram showing a part of FIG. 3.

FIG. 5A, FIG. 5B, FIG. 5C and FIG. 5D are explanatory diagrams enlarging a part of FIG. 4 to show various forms of notch portion.

FIG. 6 is a schematic cross-sectional view seen along a line VI-VI of FIG. 5A.

### DETAILED DESCRIPTION

Various embodiments will be described hereinafter with reference to the accompanying drawings. In the drawings, the same portions are represented by the same reference numbers.

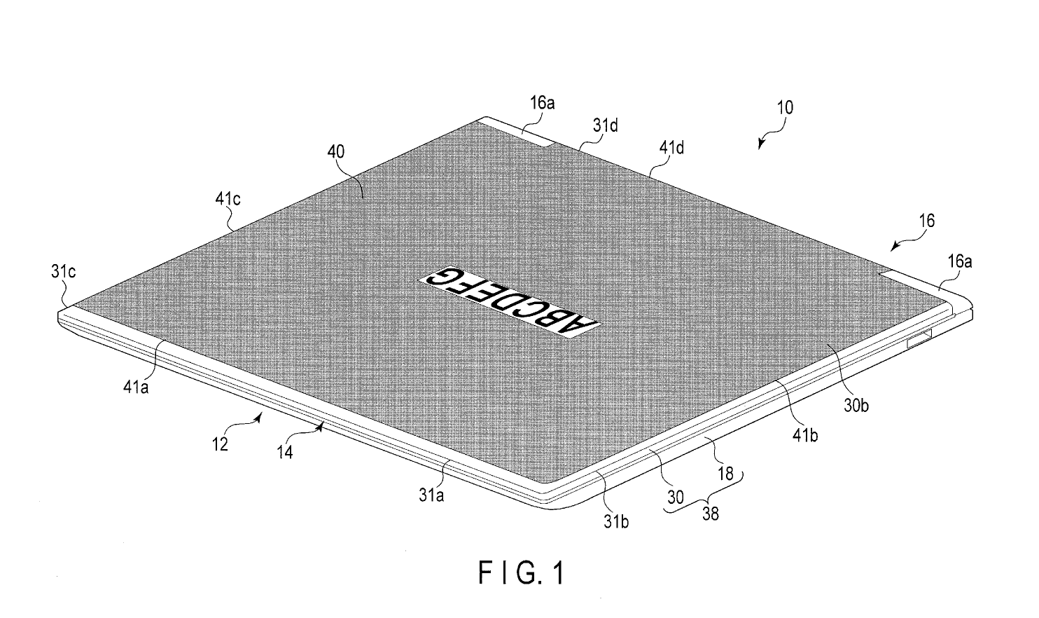

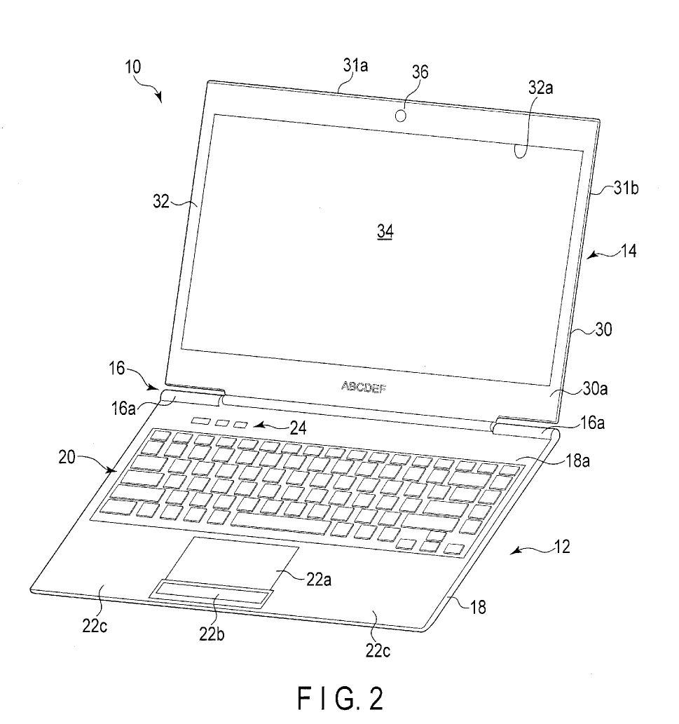

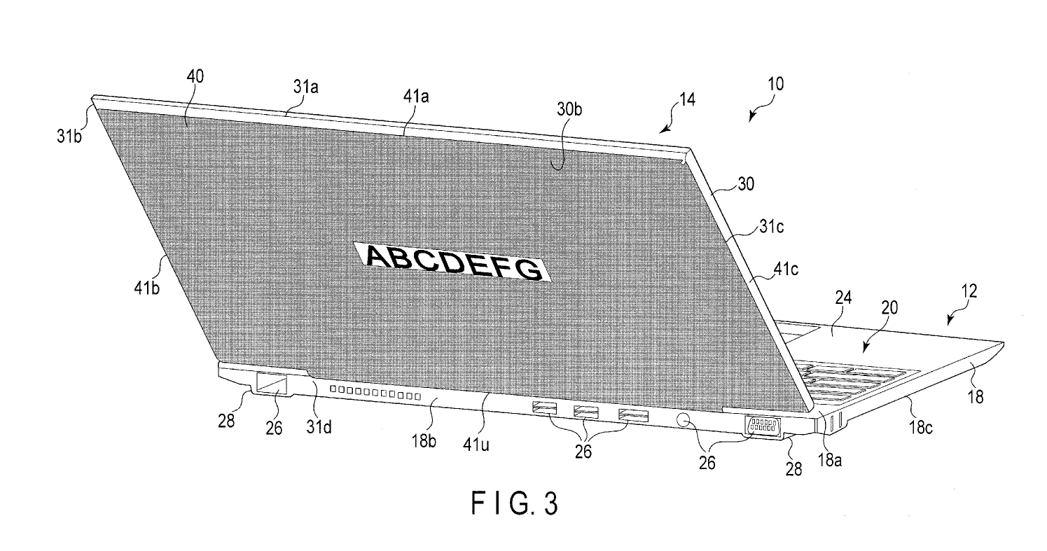

FIG. 1 to FIG. 4 show a portable computer 10 as an example of an electronic device. The portable computer 10 is formed in a notebook size and comprises an apparatus body 12 and a display unit 14 held at an end of the apparatus body 12 so as to be freely rotatable. The display unit 14 can be freely rotated between a closed position overlying the apparatus body 12 shown in FIG. 1 and an open position shown in FIG. 2 and FIG. 3 by a hinge portion 16. The display unit 14 can be held in an arbitrary rotated position with respect to the apparatus body 12 by the user hooking their fingers under a front side of the display unit 14 and rotating the display unit 14 about the hinge portion 16.

As shown in FIG. 2, the apparatus body 12 comprises a main housing 18 having a thin box-shaped structure. A keyboard 20 is arranged in an approximately central area of an upper surface 18a of the main housing 18, i.e., a surface covered with the display unit 14 when the display unit 14 is set in the closed position. A touchpad 22a, a click button 22b and an armrest portion 22c are arranged on a front side which is positioned on the user's side when the display unit 14 is opened. An indicator 24 is provided on an innermost side adjacent to the hinge portion 16. A switch button, a microphone or other arbitrary necessary means can be also provided on the upper surface 18a.

The main housing 18 accommodates various elements necessary for functions of the portable computer 10 or functional members such as a hard disk drive, a battery, a main circuit board, various subsidiary circuit boards, a speaker, an optical drive, a cooling system, etc. (not shown). Such internal members can execute required processing in accordance with signals sent via input interfaces such as the keyboard 20, the touchpad 22a, the click button 22b, etc., and display a necessary image on the display unit 14.

As shown in FIG. 3, various forms of openings 26, for example, various connection ports for connectors, openings for ventilation, openings for emitting sound from the speaker, etc., are formed on a rear end surface 18b adjacent to the upper surface 18a on a side of the hinge portion 16. Furthermore, a plurality of protruding portions 28 are formed on an innermost side of an under surface 18c of the main housing 18. When the computer 10 is placed on the flat surface of a desk, etc., ventilation in the main housing 18 can be secured through a space formed between the desk and the under surface 19c, and the upper surface 18a can be positioned obliquely with respect to the desk.

As especially clearly shown in FIG. 2, the display unit 14 comprises a sub-housing 30 having a flat structure and accommodating a liquid crystal panel. A display window 32a defined by a frame portion 32 is formed on an inner surface 30a of the sub-housing 30 which covers the upper surface 18a of the apparatus body 12 when the display unit 14 is closed. An image display portion 34 of the liquid crystal panel accommodated in the sub-housing 30 is exposed to the outside through the display window 32a. A camera lens 36 is arranged on the frame portion 32.

As shown in FIG. 1, when the display unit 14 is closed, i.e., when the display unit 14 and the apparatus body 12 overlap each other, the portable computer 10 of the present embodiment is comprised of the main housing 18 and the sub-housing 30, and totally forms a housing 38 having a plate-like or low-profile (low height) box-shaped form. Since the apparatus body 12 overlaps the display unit 14, the upper surface 18a of the apparatus body 12 and the inner surface 30a of the display 14 are opposed to each other. For example, an outer periphery portion of the upper surface 18a abuts on the frame portion 32 of the inner surface 30a, and various means such as the keyboard 20, etc., arranged on the upper surface of the apparatus body 12 and the display portion 34 are protected without being in contact with each other between the upper surface 18a and the inner surface 30a. Instead of the above structure, a stopper portion (not shown) which prevents the members in the upper surface 18a and the display portion 34 of the inner surface 30a from directly being in contact with each other may be provided on at least one of these surfaces.

An outer surface 30b of the display unit 14 is positioned on the opposite side of the inner surface 30a on which the display window 32a is formed, and forms a top surface of the housing 38. When the display unit 14 is closed, a height of side surfaces of the low-profile housing 38 is small, and the outer surface 30b of the display unit 14 forms the most conspicuous surface as a top surface of the portable computer 10. The outer surface 30b is flat as a whole and a logotype indicating, for example, a trade name, a manufacturer, etc., may be marked thereon. Such a logotype is represented by the letters “ABCDEFG” in FIG. 1.

As described above, the outer surface 30b of the display unit 14 which attracts people's attention the most is totally formed as a decorative surface. Accordingly, if the outer surface 30b is damaged by, for example, a scratch, etc., the damage is conspicuous. In particular, when the outer surface 30b is covered with a coating and formed as a glossy surface, the outer surface 30b can be easily damaged. Such damage decreases the value of the portable computer 10 as a product. Therefore, a protective sheet 40 is attached to the entire outer surface 30b of the display unit 14 to prevent the outer surface 30b from being damaged before the portable computer 10 is packaged for shipping.

As shown in FIG. 1, in the present embodiment, the outer surface 30b of the display unit 14 which forms the top surface of the housing 38 is defined by four edges 31a to 31d with respect to four side surfaces (i.e., surfaces between the inner surface 30a and the outer surface 30b) of the sub-housing 30. The outer surface 30b or the top surface of the housing 38 as a whole has a rectangular form as seen from the above. The edges 31b and 31c linearly extend on both sides of the hinge portion 16. The edge 31a linearly extends on a side opposite to the hinge portion 16 and is joined to the edges 31b and 31c. The edge 31d is positioned on the side of the hinge portion 16, and is formed as a bent structure in which the edge 31d is slightly recessed along side portions 16a of the hinge portion 16 which belong to the main housing 18 and joined to the edges 31b and 31c, and a central portion between both the side portions 16a projects from the edge 31a to the opposite side.

The protective sheet 40 has a rectangular external form corresponding to the outer surface 30b of the display unit 14 and is defined by four sides 41a to 41d, which are positioned so as to overlap the corresponding edges 31a to 31b of the outer surface 30b or to be inside the corresponding edges 31a to 31d. Accordingly, the protective sheet 40 covers approximately all the region of the flat outer surface 30b, and does not protrude to the outside of the outer surface 30b. Therefore, the protective sheet 40 is not obstructive, but can reliably protect the outer surface 30b regardless of whether the display unit 14 is set in the closed position shown in FIG. 1 or the open position shown in FIG. 2 to FIG. 4.

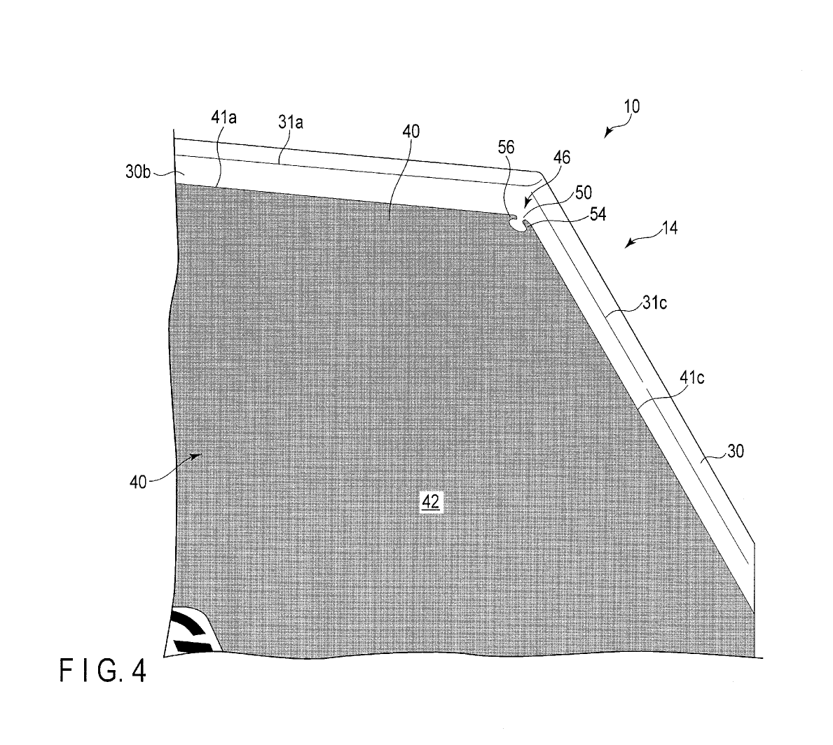

FIG. 4 to FIG. 6 show details of the protective sheet 40.

As shown in FIG. 6, the protective sheet 40 of the present embodiment is formed as a laminated body comprised of a sheet body 42 and an adhesive layer 44 applied to one entire surface of the sheet body 42. The sheet body 42 and the adhesive layer 44 are formed of a material sufficiently more flexible than that of a material of the sub-housing 30 and attached firmly to the outer surface 30b. The adhesive layer 44 is formed so as to reliably keep the protective sheet 40 on the outer surface 30b without unintentionally separating the protective sheet 40 from the outer surface 30b and to allow the protective sheet 40 to be cleanly peeled off later without leaving adhesive on the outer surface 30b. The sheet body 42 and the adhesive layer 44 should preferably be transparent or semitransparent such that the outer surface 30b is visible from the outside through the protective sheet 40.

As shown in FIG. 4, the protective sheet 40 further comprises a notch portion 46 obtained by cutting out a part of the sheet body 42 together with the adhesive layer 44 so as to facilitate the peeling off of the protective sheet 40 from the outer surface 30b of the housing 38. The notch portion 46 comprises a closing end 48 positioned in the sheet body 42 and an opening end 50 opening to the outside in the outer peripheral sides 41a and 41c. FIG. 4 shows the notch portion 46 positioned at a corner portion between the edges 31a and 31c on the upper side when the display unit 14 is stood. However, the notch portion 46 can be formed at a plurality of arbitrary portions if the peeling off of the protective sheet 40 can be facilitated.

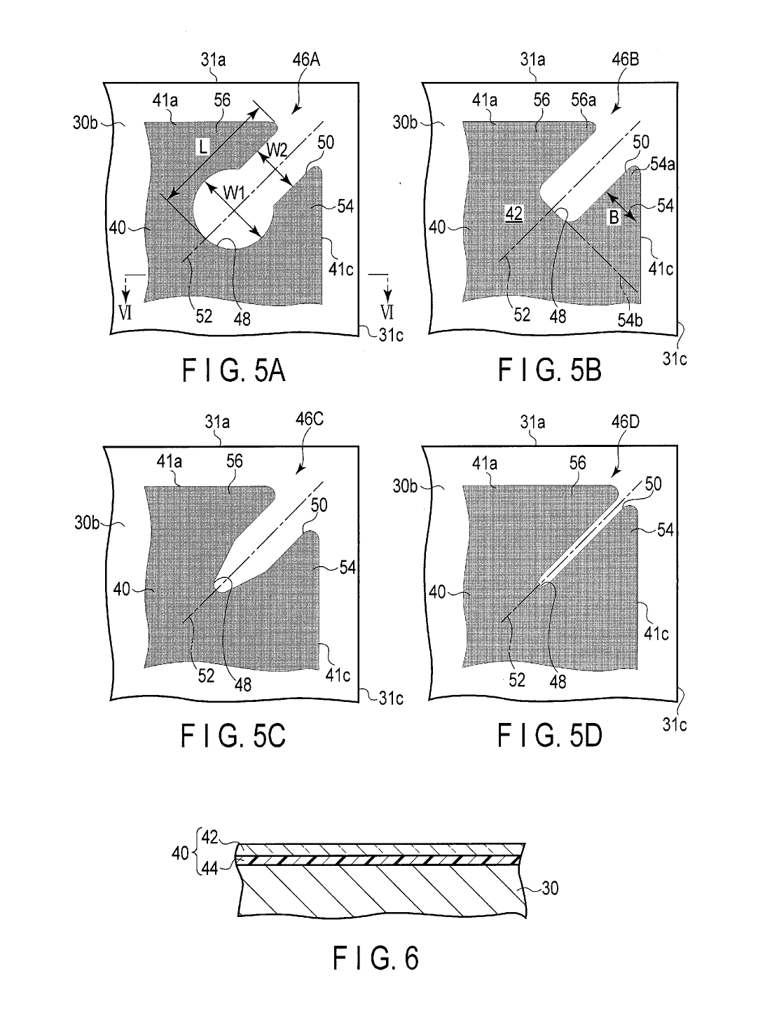

Various forms of notch portions 46A to 46D are exemplified in FIG. 5A to FIG. 5D.

A notch portion 46A shown in FIG. 5A extends in an extending direction connecting the closing end 48 and the opening end 50 along a bisector 52 of a corner portion between the sides 41a and 41c. The notch portion 46A is comprised of a circular opening portion on the side of the closing end 48 and a rectangular opening portion on the side of the opening end 50. A width W2 (in a direction orthogonal to the line 52) of the rectangular opening portion on the side of the opening end 50 is smaller than a maximum width W1, i.e., a diameter of the circular opening portion on the side of the closing end 48. A length L between the closing end 48 and the opening end 50 is longer than the maximum width W1. It should be noted that W and L indicating the width and the length are omitted in FIG. 5B to FIG. 5D so as to clarify diagrammatic representation.

A notch portion 46B shown in FIG. 5B is formed in a rectangular form having a constant width from the closing end 48 to the opening end 50. A notch portion 46C shown in FIG. 5C is formed in a triangular form having a width narrowed from an intermediate portion in the length direction to the closing end 48. A notch portion 46D shown in FIG. 5D as a whole is formed in an elongated rectangular form and the length of the notch portion 46D is longer than the length of the notch portion 46B.

The notch portion 46 can be formed in arbitrary forms and sizes in addition to the exemplified forms, but it is preferable to make the area for protecting the upper surface 30b as large as possible by making the area of the notch portion 46 as small as possible.

Tab portions 54 and 56 of which adhesive force against the outer surface 30b is decreased and which are easily peeled off from the outer surface 30b are formed on at least one side with respect to the extending direction of the notch portion 46.

In the present embodiment, since the notch portion 46 is formed at the corner portion of the protective sheet 40, the tab portions 54 and 56 are formed in a triangular form substantially equal in size or area on both sides sandwiching the extending direction of the notch portion 46.

As exemplified by the tab portion 54 in FIG. 5B, each tab 54 has a width B gradually increased from a top portion 54a of a region adjacent to the opening end 50 to a bottom portion 54b adjacent to the closing end 48, and is integrated with the sheet body 42 in the bottom portion 54b. It should be noted that the bottom portion 54b is a region on an imaginary line extending from the closing end 48 in the direction orthogonal to the line 52.

In such a tab 54, the width B of the top portion 54a of the notch portion 46B is the narrowest and the adhesive force between the top portion 54a and the upper surface 30b is the weakest. Therefore, for example, when the user peels the protective sheet 40 off before using the portable computer 10, the top portion 54a of the tab 54 can be easily peeled off by turning over the top portion 54a by the fingers.

When the top portion 54a is moved toward the closing end 48 of the notch portion 46, the adhesive force is gradually increased, but the width B of the tab portion 54 is also gradually increased. The tab portion 54 can be thereby easily peeled off to the bottom portion 54b without being broken in midstream. Although the adhesive force is increased when the tab portion 54 is peeled off to the bottom portion 54b, stress is not concentrated at the closing end 48 owing to the form, and the force applied to the bottom portion 54b is sufficiently transmitted to the adjacent portion. The strength of the sheet body 42 in the region adjacent to the bottom portion 54b is also increased and the protective sheet 40 is easily peeled off from the upper surface 30b.

As described above, the tab portions 54 and 56 formed adjacent to the notch portion 46, in particular, the top portions 54a and 56a of the tab portions 54 and 56 are held on the upper surface 30b by the adhesive force without protruding to the outside of the edges 31a to 31d of the upper surface 30b. In addition, since the top portions 54a and 56a are held on the upper surface 30b by the adhesive force, the tab portions 54 and 56 are not lifted from the upper surface 30b.

Therefore, inconvenience of snagging the tab portions 54 and 56 of the protective sheet 40 on the other members, turning up the tab portions 54 and 56, etc., during handling at manufacturing does not occur. Therefore, work efficiency at manufacturing is increased and damage to a product is efficiently avoided. In addition, since the tab portions 54 and 56 are arranged inside the sides 41a to 41d of the protective sheet 40 without protruding therefrom, a yield at manufacturing the protective sheet 40 is high and a manufacturing cost can be reduced.

The example of forming the notch portion 46 at one corner portion of the protective sheet 40 is described, but a plurality of notch portions 46 can also be provided. In particular, when the area of a surface to be protected such as the upper surface 30b, etc., of the housing 38 is large, the protective sheet 40 can be easily peeled off by providing a plurality of notch portions 46 and tab portions 54 and 56 adjacent to each of these notch portions 46. Such a protective sheet 40 is not limited to the portable computer 10, but can also be used for protecting glossy and attractive surfaces of cellphones, home electric appliances, furniture, etc., and protecting glass surfaces.

By the above-described protective sheet 40 and the electronic device 10 of the present embodiment, operations in handling products can be efficiently conducted and damage to products in handling can be efficiently avoided at low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

### LIST OF REFERENCE NUMERALS

10 . . . electronic device
12 . . . apparatus body
14 . . . display unit
16 . . . hinge portion
18 . . . main housing
20 . . . keyboard
22a . . . touchpad
22b . . . click button
22c . . . armrest portion
24 . . . indicator
26 . . . opening
28 . . . protruding portion
30 . . . sub-housing
30a . . . inner surface
30b . . . outer surface
31a-31d . . . edge
32 . . . frame portion
32a . . . display window
34 . . . display portion
36 . . . camera lens
38 . . . housing
40 . . . protective sheet
41a-41d . . . side
42 . . . sheet body
44 . . . adhesive layer
46, 46A, 46B, 46C, 46D . . . notch portion
48 . . . closing end
50 . . . opening end
52 . . . bisector
54, 56 . . . tab portions
54a . . . top portion
54b . . . bottom portion
B . . . width of tab
L . . . length
W . . . width

What is claimed is:

1. A protective sheet attached to an outer surface of a housing of an electronic device comprising at least one flat outer surface comprising a perimeter defined by a plurality of edges protective of the housing, the protective sheet comprising:
a sheet body comprising a material more flexible than that of the housing, and comprising an external form defined by sides extending along the edges of the electronic device;
an adhesive layer on one entire surface of the sheet body;
a notch portion comprising a closing end in the sheet body and an opening end at one of the sides, the notch portion extending in a direction from the closing end toward the opening end; and
a tab portion formed on at least one side of the sheet body with respect to the direction of the notch portion, and easily peelable off from the outer surface.

2. The protective sheet of claim 1, wherein
the sides of the sheet body are positioned inside the edges of the outer surface of the housing, in the outer surface.

3. The protective sheet of claim 1, wherein
the sheet body comprises a rectangular form, and the notch portion is formed at at least one corner portion.

4. The protective sheet of claim 1, wherein
the tab portion is formed between the notch portion and the side adjacent to the notch portion, a dimension between the notch portion and the side is gradually decreased toward the opening end, and the tab portion comprises a rounded top.

5. The protective sheet of claim 1, wherein
the notch portion comprises a length along the direction, and the length is greater than a width of the opening end orthogonal to the direction.

6. An electronic device comprising:
a housing comprising at least one flat outer surface comprising a perimeter defined by a plurality of edges; and
a protective sheet attached to the outer surface of the housing and protecting the housing,
the protective sheet comprising:
a sheet body comprising a material more flexible than that of the housing, and comprising an external form defined by sides extending along the edges of the housing;
an adhesive layer on an entire surface of the sheet body on a side of the outer surface;
a notch portion comprising a closing end in the sheet body and an opening end at one of the sides, the notch portion extending in a direction from the closing end toward the opening end; and
a tab portion formed on at least one side of the sheet body with respect to the direction of the notch portion, and easily peelable off from the outer surface.

7. The electronic device of claim 6, wherein
the sides of the sheet body are positioned inside the edges of the outer surface of the housing, in the outer surface.

8. The electronic device of claim 6, wherein
the sheet body comprises a rectangular form, and the notch portion is formed at at least one corner portion.

9. The electronic device of claim 6, wherein
the tab portion is formed between the notch portion and the side adjacent to the notch portion, a dimension between the notch portion and the side is gradually decreased toward the opening end, and the tab portion comprises a rounded top.

10. The electronic device of claim 6, wherein
the notch portion comprises a length along the direction, and the length is greater than a width of the opening end orthogonal to the direction.

11. The electronic device of claim 6, wherein
the sheet body and the adhesive layer are transparent.
